(19) United States
(12) Patent Application Publication
(10) Pub. No.: US 2020/0006212 A1
(43) Pub. Date: Jan. 2, 2020

(54) SEMICONDUCTOR PRODUCT SUBSTRATE INCLUDING STRESS RELIEF LAYER

(71) Applicant: WESTERN DIGITAL TECHNOLOGIES, INC., San Jose, CA (US)

(72) Inventors: Rui Guo, Shanghai (CN); Songtao Lu, Shanghai (CN); Shenghua Huang, Shanghai (CN); Ting Liu, Shanghai (CN); Chin-Tien Chiu, Taichung City (TW)

(73) Assignee: WESTERN DIGITAL TECHNOLOGIES, INC., San Jose, CA (US)

(21) Appl. No.: 16/277,244

(22) Filed: Feb. 15, 2019

(30) Foreign Application Priority Data
Jun. 28, 2018 (CN) 201810690328.9

(51) Int. Cl. H01L 23/498; H01L 23/00; H01L 25/065; H01L 21/48

(52) U.S. Cl. CPC H01L 23/49822; H01L 23/49816; H01L 23/562; H01L 2924/3511; H01L 24/49; H01L 21/4857; H01L 25/0657

(57) ABSTRACT

A substrate is disclosed having a stress relief layer. The stress relief layer may be applied to a dielectric core of the substrate, beneath a conductive layer in which electrical traces and contact pads are formed. The substrate including the stress relief layer may be incorporated into a semiconductor product which may, for example, be mounted on a host printed circuit board using solder balls on a surface of the substrate. The stress relief layer helps dissipate stresses within the substrate and improves the board level reliability.

### BACKGROUND

The strong growth in demand for portable consumer electronics is driving the need for high-capacity storage devices. Non-volatile semiconductor memory devices are becoming widely used to meet the ever-growing demands on digital information storage and exchange. Their portability, versatility and rugged design, along with their high reliability and large capacity, have made such memory devices ideal for use in a wide variety of electronic products, including for example digital cameras, digital music players, video game consoles, computer SSDs, PDAs and cellular telephones.

While many varied packaging configurations are known, flash memory semiconductor products may in general be fabricated as system-in-a-package (SIP) or multichip modules (MCM), where a plurality of semiconductor die are mounted and interconnected to an upper surface of a small footprint substrate. The substrate may in general include a rigid, dielectric base having a conductive layer etched on one or both sides. Solder balls are often mounted on contact pads formed on a lower surface of the substrate to allow the substrate to be soldered to a host device such as a printed circuit board. Once mounted, signals may be transferred between the semiconductor die and the host device via the substrate.

In conventional board level semiconductor product, mechanical stresses often generate at the solder ball junction between substrate pad and PCB (printed circuit board) pad. For example, these stresses can be generated as a result of different coefficients of thermal expansion of the semiconductor package and PCB, for example during thermal cycling tests of the board level semiconductor product. These stresses can also be generated as a result of impact shock to the solder balls, for example during drop testing of the semiconductor product. Such stresses can result in cracks to the solder balls, separation of the solder balls from the contact pads and/or breakage of the trace at the connection point to the contact pad, all of which can result in board level reliability (BLR) failure.

### DESCRIPTION OF THE DRAWINGS

FIG. 1 is a flowchart of the overall fabrication process of a substrate and a semiconductor product using that substrate according to embodiments of the present technology.

FIG. 2 is a side view of a substrate of a semiconductor product at a first step in the fabrication process according to an embodiment of the present technology.

FIG. 3 is a bottom view of the substrate of FIG. 2.

FIG. 4 is a side view of a substrate of a semiconductor product at a second step in the fabrication process according to an embodiment of the present technology.

FIG. 5 is a top view of the substrate of FIG. 4.

FIG. 6 is a side view of a substrate of a semiconductor product at a third step in the fabrication process according to an embodiment of the present technology.

FIG. 7 is a top view of the substrate of FIG. 6.

FIG. 8 is a bottom view of the substrate of FIG. 6.

FIG. 9 is a side view of a number of semiconductor die mounted on a substrate according to embodiments of the present technology.

FIG. 10 is a perspective view of a number of semiconductor die mounted on, and wire bonded to, a substrate according to embodiments of the present technology.

FIG. 11 is a side view of a completed semiconductor product according to embodiments of the present technology.

FIG. 12 is a bottom view of the semiconductor product of FIG. 11.

FIGS. 13 and 14 are bottom views of a substrate including stress relief layers according to alternative embodiments of the present technology.

### DETAILED DESCRIPTION

The present technology will now be described with reference to the figures, which in embodiments, relate to a substrate having a stress relief layer. The stress relief layer may be applied to a dielectric core of the substrate, beneath a conductive layer in which electrical traces and contact pads are formed. The substrate including the stress relief layer may be incorporated into a semiconductor product which may, for example, be mounted on a host printed circuit board using solder balls on a surface of the substrate. The stress relief layer helps dissipate stresses within the substrate and improves the board level reliability.

It is understood that the present technology may be embodied in many different forms and should not be construed as being limited to the embodiments set forth herein. Rather, these embodiments are provided so that this disclosure will be thorough and complete and will fully convey the technology to those skilled in the art. Indeed, the technology is intended to cover alternatives, modifications and equivalents of these embodiments, which are included within the scope and spirit of the technology as defined by the appended claims. Furthermore, in the following detailed description of the present technology, numerous specific details are set forth in order to provide a thorough understanding of the present technology. However, it will be clear to those of ordinary skill in the art that the present technology may be practiced without such specific details.

The terms “top” and “bottom,” “upper” and “lower” and “vertical” and “horizontal” as may be used herein are by way of example and illustrative purposes only, and are not meant to limit the description of the technology inasmuch as the referenced item can be exchanged in position and orientation. Also, as used herein, the terms “substantially,” “approximately” and/or “about” mean that the specified dimension or parameter may be varied within an acceptable manufacturing tolerance for a given application. In one embodiment, the acceptable manufacturing tolerance is ±2.5% of a given dimension.

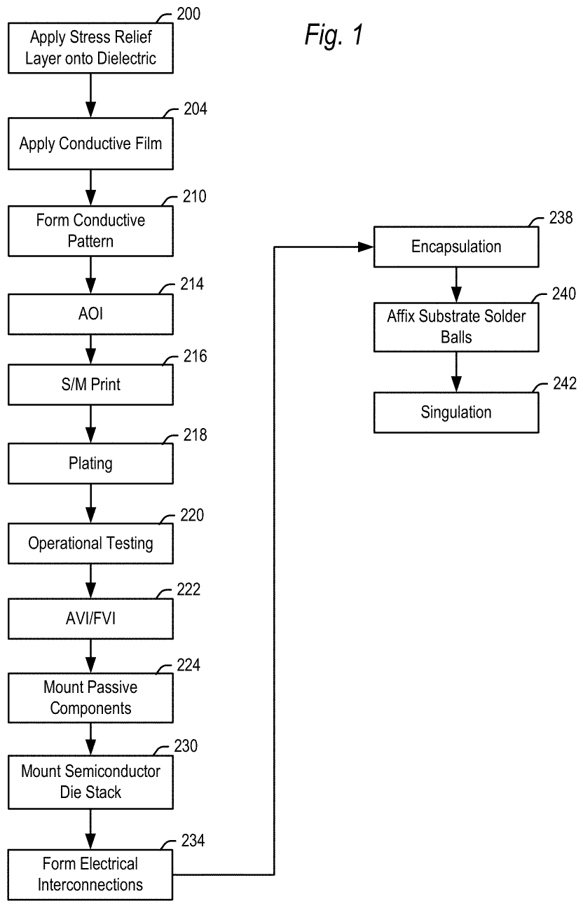

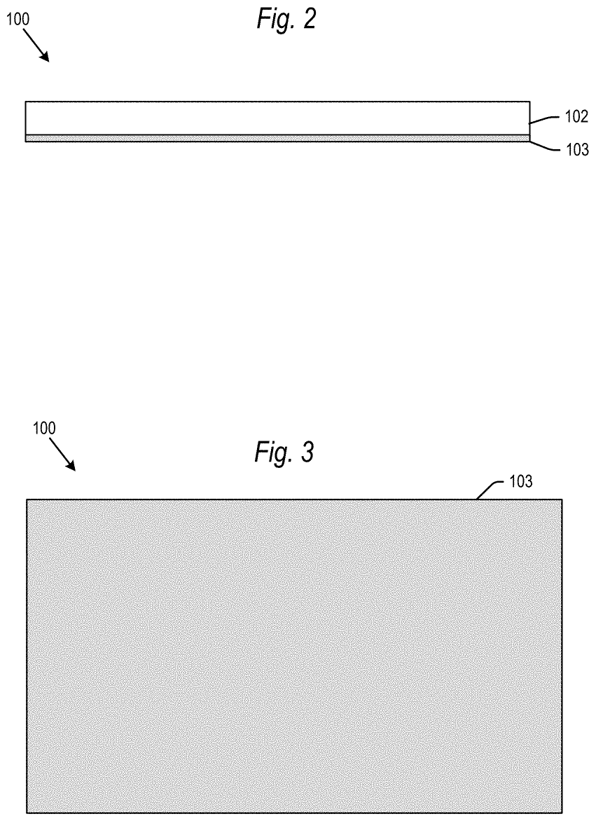

An embodiment of the present technology will now be explained with reference to the flowchart of FIG. 1 and the top, side and perspective views of FIGS. 2 through 12. Although the figures show an individual semiconductor product 150, or a portion thereof, it is understood that the device 150 may be batch processed along with a plurality of other semiconductor products on substrate panels to achieve economies of scale. The number of rows and columns of devices 150 on the substrate panels may vary.

The substrate panel for the fabrication of semiconductor product 150 begins with a plurality of substrates 100 (again, one such substrate is shown in FIGS. 2-8). The substrate 100 may be a variety of different chip carrier mediums, including a printed circuit board (PCB), a leadframe or a tape automated bonded (TAB) tape. Where substrate 100 is a PCB, the substrate may be formed of a core 102 as shown in FIG. 2. The core 102 may be formed of various dielectric materials such as for example, polyimide laminates, epoxy resins including FR4 and FR5, bismaleimide triazine (BT), and the like. The core may have a thickness of between 40 microns (μm) to 200 μm, although the thickness of the core may vary outside of that range in alternative embodiments. The core 102 may be ceramic or organic in alternative embodiments.

In accordance with aspects of the present technology, a stress relief layer 103 may be formed on the dielectric core 102 in step 200, as shown in the edge and bottom views of FIGS. 2 and 3, respectively. The stress relief layer may be any of a variety of elastic films having a modulus that is lower than that of the comparatively rigid dielectric core 102. In embodiments, the modulus of the stress relief layer 103 may for example be 100 MPa to 1000 MPa, and possibly around 300 MPa to 500 MPa. The stress relief layer 103 may be formed of various dielectric materials, including for example polyimide (PI), Polybenzoxazole (PBO), Benzocyclobutene (BCB), various silicone compounds, and various rubbers. The stress relief layer 103 may be formed of other materials in further embodiments. In embodiments, the stress relief layer 103 may have a thickness of between 10 μm to 50 μm, such as for example 20 μm to 25 μm. The stress relief layer 103 may be thinner or thicker than that in further embodiments.

Further properties of the stress relief layer 103 may include a Poisson's ratio of 0.25 to 0.5 such as for example 0.33 to 0.35. It may have a coefficient of thermal expansion ranging between 20 PPM and 60 PPM, such as for example 30 PPM. The stress relief layer 103 may be applied to the dielectric core 102 by any of a variety of processes, including for example thin film deposition, vapor deposition, printing, spin coating, dry film lamination or other methods. In embodiments, the stress relief layer 103 may be applied to a single major planar surface of the dielectric core 102. However, the stress relief layer 103 may be applied to both major planar surfaces of the dielectric core 102 in further embodiments.

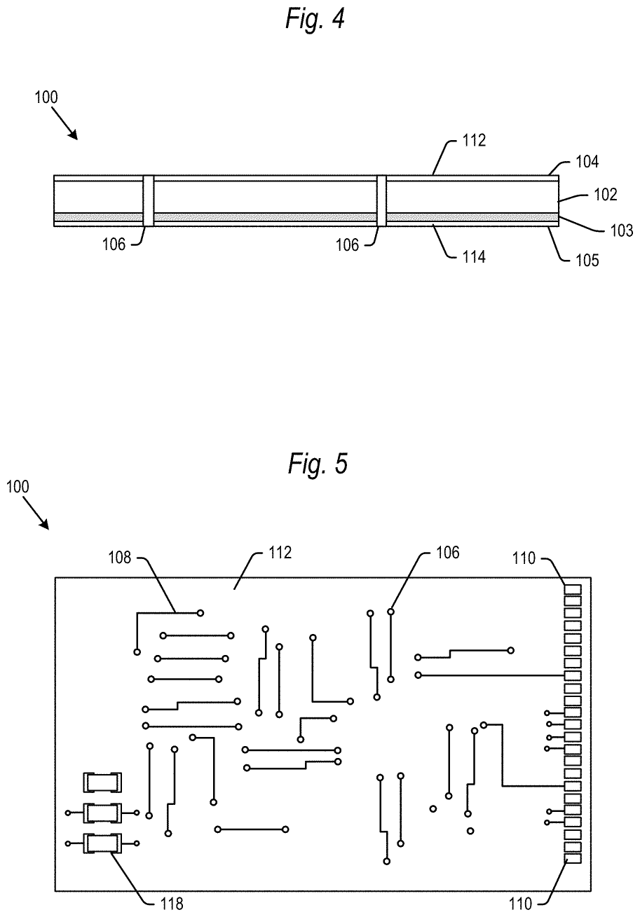

In step 204, conductive layers 104 and 105 may next be formed on the exposed planar surfaces of the substrate 100, as shown in the edge and top views of FIGS. 4 and 5, respectively. For example, where the stress relief layer 103 is formed on one surface of the dielectric core 102, conductive layer 104 may be formed on the exposed major planar surface of the dielectric core 102. The conductive layer 105 may be formed on the exposed major planar surface of the stress relief layer 103.

The conductive layers 104, 105 may be formed of copper or copper alloys, plated copper or plated copper alloys, Alloy 42 (42Fe/58Ni), copper plated steel, or other metals and materials suitable for use on substrate panels. The conductive layers 104, 105 may have a thickness of about 8 μm to 40 μm, although the thickness of the layers may vary outside of that range in alternative embodiments.

In a step 210, a conductive pattern of vias, leads and/or pads are formed in and through the substrate 100. The substrate 100 may drilled to define through-hole vias 106, which are subsequently plated and/or filled with a conductive metal. A conductance pattern of electrical traces 108 and contact pads 110 may then be formed on the top and/or bottom major planar surfaces of substrate 100. FIG. 5 shows an example of a conductance pattern including traces 108 and contact pads 110 formed on a first major planar surface 112 of substrate 100. FIG. 8 shows an example of a conductance pattern including traces 108 and contact pads 110 formed on a second major planar surface 114 of substrate 100.

The pattern of vias, 106, traces 108 and contact pads 110 shown on surfaces 112 and 114 in the figures are by way of example, and the substrate 100 may include more or less vias, traces and/or contact pads in further embodiments, and they may be in different locations in further embodiments. The conductance pattern on the top and/or bottom surfaces of the substrate 100 may be formed by a variety of known processes, including for example various photolithographic processes.

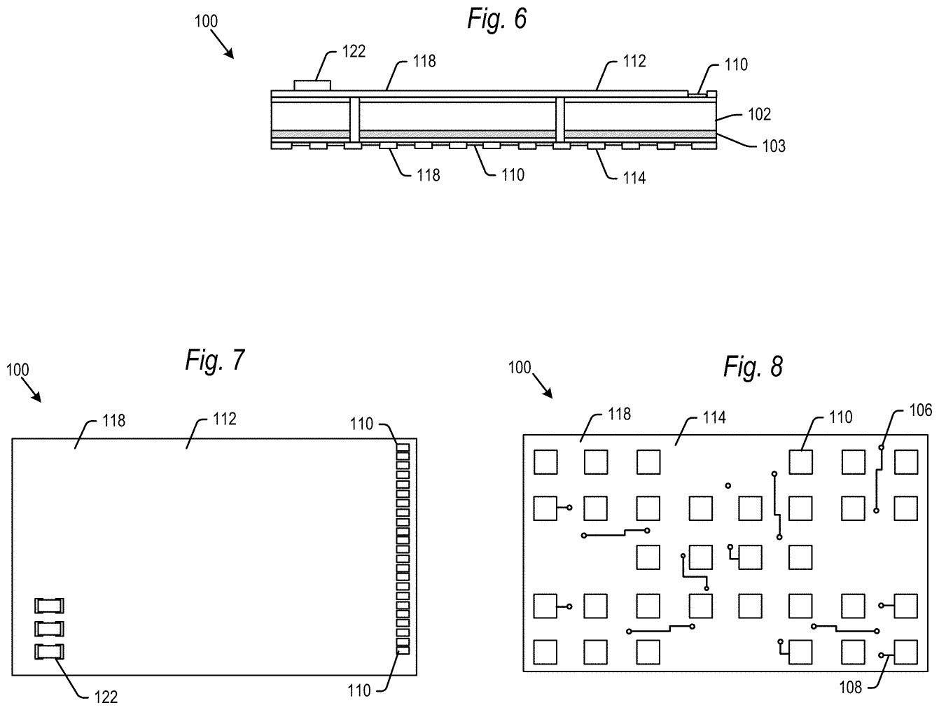

Referring again to FIG. 1, the substrate 100 may next be inspected in step 214. This step may include an automatic optical inspection (AOI). Once inspected, a solder mask 118 may be applied to the upper and/or lower surfaces of the substrate in step 216, as shown in the edge, top and bottom views of FIGS. 6, 7 and 8, respectively. After the solder mask is applied, the contact pads 110, and any other areas to be soldered on the conductance patterns may be plated, for example, with a Ni/Au, Alloy 42, or the like, in step 218 in a known electroplating or thin film deposition process. The substrate 100 may next undergo operational testing in step 220 to ensure the substrate 100 is working properly. In step 222, the substrate may be visually inspected, including for example an automated visual inspection (AVI) and a final visual inspection (FVI) to check for contamination, scratches and discoloration. One or more of these steps may be omitted or performed in a different order in further embodiments.

Assuming the substrate 100 passes inspection, passive components 122 (FIGS. 6 and 7) may next be affixed to the substrate 100 in a step 224. The one or more passive components may include for example one or more capacitors, resistors and/or inductors, though other components are contemplated. The passive components 122b shown are by way of example only, and the number, type and position may vary in further embodiments.

In embodiments, the present technology may relate to the substrate 100 described above and shown for example in FIGS. 6-8. As explained hereinafter, solder balls may be affixed to the contact pads 110, for example on the second (bottom) major planar surface 114 as shown in FIG. 8. As discussed below, providing the stress relief layer 103 within the substrate 100 serves to reduce mechanical stresses between the solder balls and the contact pads 110 which may otherwise develop due to thermal mismatch, impact shocks or other stress-generating forces on the substrate 100.

The above-described substrate 100 may have a thickness ranging between 0.05 mm and 0.3 mm, and more particularly 0.08 mm or 0.21 mm. It is understood that the substrate 100 may have other thicknesses in further embodiments. In embodiments described above, the substrate 100 is a two layer substrate (two conductive layers sandwiched on a dielectric layer). In further embodiments, the substrate 100 may include more layers, such as for example a four layer substrate (four conductive layers interspersed around three dielectric layers).

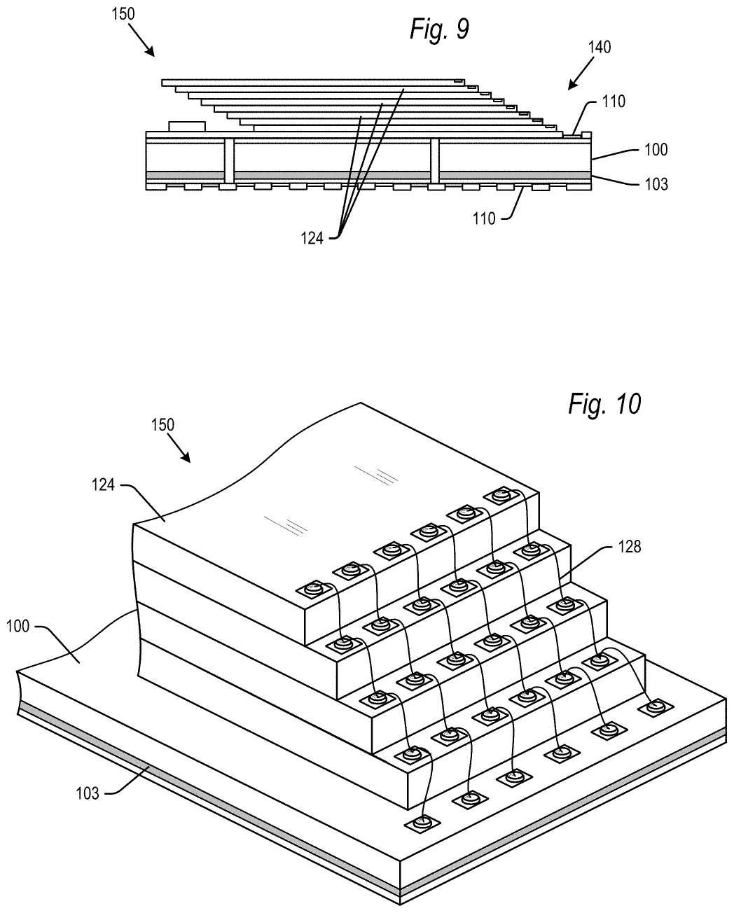

In further embodiments, the present technology may relate to a semiconductor product 150 formed using the substrate 100 described above. In particular, in step 230, one or more semiconductor die 124 may be mounted on the substrate 100, as shown in the edge view of FIG. 9. The semiconductor die 124 may for example be memory die such as 2D NAND flash memory or 3D BiCS (Bit Cost Scaling), V-NAND or other 3D flash memory, but other types of die 124 may be used. These other types of semiconductor die include but are not limited to controller die such as an ASIC, or RAM such as an SDRAM, DDR SDRAM, LPDDR and GDDR.

Where multiple semiconductor die 124 are included, the semiconductor die 124 may be stacked atop each other in an offset stepped configuration to form a die stack as shown for example in FIG. 9. The number of die 124 shown in the stack is by way of example only, and embodiments may include different numbers of semiconductor die, including for example 1, 2, 4, 8, 16, 32 or 64 die. There may be other numbers of die in further embodiments. The die may be affixed to the substrate and/or each other using a die attach film. As one example, the die attach film may be cured to a B-stage to preliminarily affix the die 124 in the stack, and subsequently cured to a final C-stage to permanently affix the die 124 to the substrate 100.

In step 234, the semiconductor die 124 may be electrically interconnected to each other and to the substrate 100. FIG. 10 shows a perspective view of wire bonds 128 being formed between corresponding die bond pads on respective die 124 down the stack, and then bonded to contact pads 110 on surface 112 of substrate 100. The wire bonds may be formed by a ball-bonding technique, but other wire bonding techniques are possible. The semiconductor die 124 may be electrically interconnected to each other and the substrate 100 by other methods in further embodiments, including by through-silicon vias (TSVs).

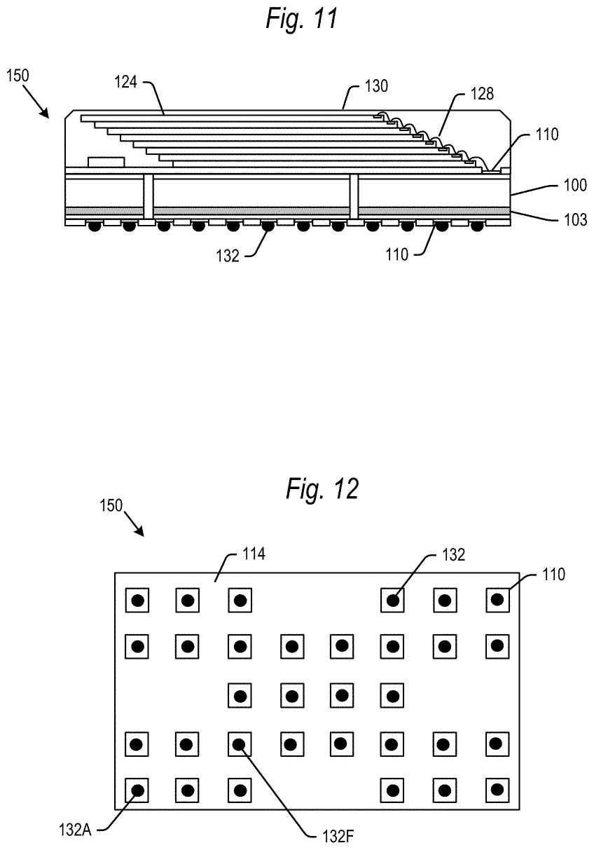

Following electrical connection of the die 124 to the substrate 100, the semiconductor product 150 may be encapsulated in a mold compound 130 in a step 238 and as shown in FIG. 11. Mold compound 130 may include for example solid epoxy resin, Phenol resin, fused silica, crystalline silica, carbon black and/or metal hydroxide. Other mold compounds from other manufacturers are contemplated. The mold compound may be applied by various known processes, including by compression molding, FFT (flow free thin) molding, transfer molding or injection molding techniques.

In step 240, solder balls 132 may be affixed to the contact pads 110 on a lower surface 114 of substrate 100 as shown in FIGS. 11 and 12. The solder balls 132 may be used to solder the semiconductor product to a host device, such as a printed circuit board. The pattern of contact pads 110 and solder balls 132 shown on the bottom surface 114 of substrate 100 in FIG. 12 is by way of example only, and may vary in further embodiments. In embodiments, the number of solder balls 132 may range from between 50 and 1000, and more particularly 70 to 500.

As noted above, the semiconductor product 150 may be formed on a panel of substrates. After formation and encapsulation of the substrates 100, the substrates 100 may be singulated from each other in step 242 to form a finished semiconductor product 150 as shown in FIG. 11. The semiconductor products 150 may be singulated by any of a variety of cutting methods including sawing, water jet cutting, laser cutting, water guided laser cutting, dry media cutting, and diamond coating wire cutting. While straight line cuts will define generally rectangular or square shaped semiconductor products 150, it is understood that semiconductor product 150 may have shapes other than rectangular and square in further embodiments of the present technology.

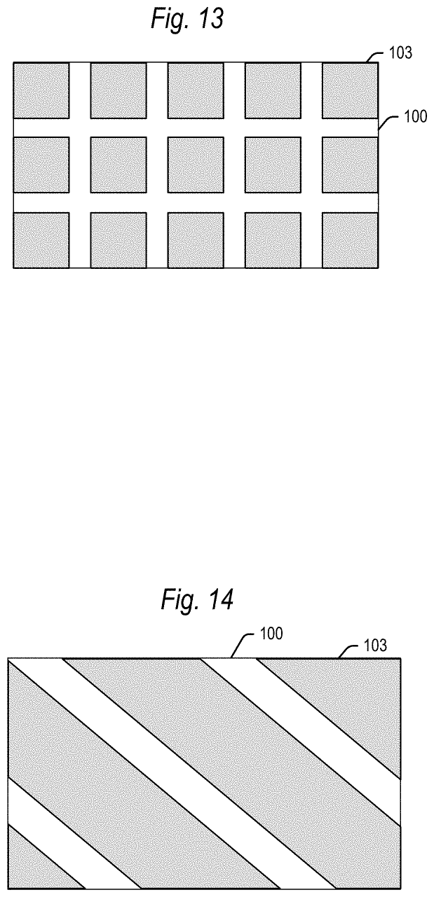

The stress relief layer 103 according to the present technology is described above as a solid layer applied continuously over the dielectric core 102. However, it need not be in further embodiments. FIGS. 13 and 14 illustrate two possibilities of a patterned stress relief layer 103 according to further embodiments. In a further embodiment, the stress relief layer may have a pattern matching the pattern of contact pads 110 on the surface 114 of the substrate 100. Other patterns are possible.

Inclusion of the stress relief layer 103 within the substrate 100 serves to improve board level reliability (BLR) which may otherwise degrade without layer 103 due to thermal mismatch, impact shocks or other stress-generating forces on the substrate 100 and within semiconductor product 150. The layer 103 is able to absorb and dissipate stresses at the junction between the contact pads 110 and solder balls 132, as well as elsewhere in the substrate 100.

Strain energy density (SED) is a good indicator to evaluate BLR performance in mechanical testing of substrates. Table 1 below indicates a comparison of the SED for solder balls during thermal cycle testing on two different groups of substrates. The first group of substrates were conventional substrates without the stress relief layer 103 (SRL). The second group of substrates were examples of substrate 100 including the SRL. For each substrate in the two groups, SED was calculated based on the visco-plastic behavior of solder balls. The first solder ball on each substrate is referred to as an Anchor Ball (in the position of solder ball 132A in FIG. 12), and it is a corner solder ball provided to bear a relatively large amount of stress. The second solder ball on each substrate is referred to as a Functional Ball (in the position of solder ball 132F in FIG. 12), as it is used in signal transfer and is positioned inward, toward a center of the substrate.

TABLE 1

| | | | | |
|---|---|---|---|---|
| SED per | | | | |
| Thermal Cycle | Test 1 | Test 2 | Test 3 | Test 4 |

| | | | | | |
|---|---|---|---|---|---|
| Substrates | Anchor | 0.378 | 0.359 | 0.359 | 0.374 |
| without | Ball | | | | |
| SRL | Functional | 0.326 | 0.310 | 0.306 | 0.333 |
| | Ball | | | | |
| Substrates | Anchor | 0.341 | 0.312 | 0.320 | 0.325 |
| with SRL | Ball | | | | |
| | Functional | 0.237 | 0.215 | 0.212 | 0.233 |
| | Ball | | | | |

The tests were performed by cycling each substrate in the first and second groups between −40° C. and 85° C., with a ramp time 15° C./min, and with a dwell time 15 mins.

In Test 1, the two substrates were both two layer substrates, 130 μm thick, with 60% copper routing coverage and no vias. As shown, the Anchor Ball and Function Ball of the substrate having the stress relief layer both had a lower measured SED than the substrate without the stress relief layer.

In Test 2, the two substrates were both four layer substrates, 170 μm thick, with 60% copper routing coverage and no vias. As shown, the Anchor Ball and Function Ball of the substrate having the stress relief layer both had a lower measured SED than the substrate without the stress relief layer.

In Test 3, the two substrates were both two layer substrates, 130 μm thick, with 40% copper routing coverage this time and no vias. As shown, the Anchor Ball and Function Ball of the substrate having the stress relief layer both had a lower measured SED than the substrate without the stress relief layer.

In Test 4, the two substrates were both two layer substrates, 130 μm thick, with 40% copper routing coverage and both included vias in this test. As shown, the Anchor Ball and Function Ball of the substrate having the stress relief layer both had a lower measured SED than the substrate without the stress relief layer.

As seen from the above tests, the inclusion of the stress release layer 103 within a substrate was effective at reducing Strain Energy Density and improving Board Level Reliability. Mechanical stresses on a substrate can also result in the substrate and/or semiconductor product warping. Testing of substrates including the stress relief layer 103 showed a reduction of 1-2 μm in warping over conventional substrates that were the same but did not include the stress relief layer.

In summary, in one example, the present technology relates to a substrate for use in a semiconductor product, comprising: a dielectric core having first and second major planar surfaces; a stress relief layer applied onto the first major planar surface of the dielectric core, the stress relief layer having a modulus less than a modulus of the dielectric core; a first conductive layer applied onto the second major planar surface of the dielectric core, the first conductive layer formed into a first conductive pattern; and a second conductive layer applied onto the stress relief layer, the second conductive layer formed into a second conductive pattern.

In another example, the present technology relates to a semiconductor product, comprising: a substrate, comprising: a dielectric core having a first major planar surface, a stress relief layer applied onto the first major planar surface of the dielectric core, the stress relief layer having a modulus less than a modulus of the dielectric core, and a first conductive layer applied onto the stress relief layer, the first conductive layer formed into a first conductive pattern; and one or more semiconductor die mounted on the substrate and electrically interconnected to the substrate.

In a further example, the present technology relates to a method of fabricating a substrate for a semiconductor product, comprising: (a) applying a dielectric film onto a dielectric core, the dielectric film having a lower modulus than the dielectric core; (b) applying a first conductive layer onto the dielectric core; (c) forming the first conductive layer into a first conductive pattern; (d) applying a second conductive layer onto the stress relief layer; (e) forming the second conductive layer into a second conductive pattern; and (f) affixing solder balls to the substrate, the dielectric film dissipating stresses between the solder balls and the substrate.

In another example, the present technology relates to a substrate for use in a semiconductor product, comprising: a dielectric core having first and second major planar surfaces; stress relief means, applied onto the first major planar surface of the dielectric core, for reducing mechanical stresses within the substrate; a first conductive layer applied onto the second major planar surface of the dielectric core, the first conductive layer formed into a first conductive pattern; and a second conductive layer applied onto the stress relief means, the second conductive layer formed into a second conductive pattern.

The foregoing detailed description of the technology has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

We claim:

1. A substrate for use in a semiconductor product, comprising:
a dielectric core having first and second major planar surfaces;
a stress relief layer applied onto the first major planar surface of the dielectric core, the stress relief layer having a modulus less than a modulus of the dielectric core;
a first conductive layer applied onto the second major planar surface of the dielectric core, the first conductive layer formed into a first conductive pattern; and
a second conductive layer applied onto the stress relief layer, the second conductive layer formed into a second conductive pattern.

2. The substrate of claim 1, wherein the stress relief layer is formed of a dielectric film.

3. The substrate of claim 1, wherein the stress relief layer is formed of one of polyimide, Polybenzoxazole, Benzocyclobutene, compound of silicone and rubber.

4. The substrate of claim 1, wherein the stress relief layer has a modulus of 100 MPa to 1000 MPa.

5. The substrate of claim 1, wherein the stress relief layer has a modulus of 300 MPa to 500 MPa.

6. The substrate of claim 1, wherein the stress relief layer is a solid layer applied continuously over the dielectric core.

7. The substrate of claim 1, wherein the stress relief layer reduces warping of the substrate.

8. The substrate of claim 1, wherein the stress relief layer dissipates mechanical stresses within the substrate.

9. The substrate of claim 1, wherein the second conductive pattern in the second conductive layer comprises a plurality of contact pads, the substrate further comprising a plurality of solder balls on the plurality of contact pads, and wherein the stress relief layer is configured to dissipate mechanical stresses between the plurality of contact pads and plurality of solder balls.

10. The substrate of claim 1, wherein the stress relief layer is between 5 μm and 50 μm thick.

11. A semiconductor product, comprising:
a substrate, comprising:
a dielectric core having a first major planar surface,
a stress relief layer applied onto the first major planar surface of the dielectric core, the stress relief layer having a modulus less than a modulus of the dielectric core, and
a first conductive layer applied onto the stress relief layer, the first conductive layer formed into a first conductive pattern; and
one or more semiconductor die mounted on the substrate and electrically interconnected to the substrate.

12. The semiconductor product of claim 11, further comprising a plurality of solder balls affixed to contact pads of the first conductive pattern, the stress relief layer configured to reduce stress between the plurality of solder balls and the contact pads.

13. The semiconductor product of claim 11, wherein the stress relief layer is formed of a dielectric film.

14. The semiconductor product of claim 11, wherein the stress relief layer has a modulus of 300 MPa to 400 MPa.

15. The semiconductor product of claim 11, wherein the stress relief layer is configured to reduce warping of the substrate.

16. The semiconductor product of claim 11, wherein the stress relief layer is configured to dissipate mechanical stresses within the semiconductor product.

17. A method of fabricating a substrate for a semiconductor product, comprising:
(a) applying a dielectric film onto a dielectric core, the dielectric film having a lower modulus than the dielectric core;
(b) applying a first conductive layer onto the dielectric core;
(c) forming the first conductive layer into a first conductive pattern;
(d) applying a second conductive layer onto the stress relief layer;
(e) forming the second conductive layer into a second conductive pattern; and
(f) affixing solder balls to the substrate, the dielectric film dissipating stresses between the solder balls and the substrate.

18. The method of claim 17, wherein said step (a) of applying a dielectric film onto a dielectric core comprises the step of applying the dielectric film by one of thin film deposition, vapor deposition, printing, spin coating and dry film lamination.

19. The method of claim 17, wherein said step (e) of forming the second conductive layer into a second conductive pattern comprises the step of forming a plurality of contact pads in the second conductive pattern, the solder balls affixed to the plurality of contact pads, the dielectric film dissipating stresses between the solder balls and the contact pads.

20. A substrate for use in a semiconductor product, comprising:
a dielectric core having first and second major planar surfaces;
stress relief means, applied onto the first major planar surface of the dielectric core, for reducing mechanical stresses within the substrate;
a first conductive layer applied onto the second major planar surface of the dielectric core, the first conductive layer formed into a first conductive pattern; and
a second conductive layer applied onto the stress relief means, the second conductive layer formed into a second conductive pattern.
